(19) United States
(12) Patent Application Publication
(10) Pub. No.: US 2004/0178702 A1
(43) Pub. Date: Sep. 16, 2004

(54) Free piston piezoelectric generator

(75) Inventors: Ulrich Bonne, Hopkins, MN (US); Burgess R. Johnson, Bloomington, MN (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc.

(21) Appl. No.: 10/386,339

(22) Filed: Mar. 11, 2003

(51) Int. Cl. H01L 41/113

(52) U.S. Cl. 310/339

(57) ABSTRACT

An electric generator includes a linear free piston micro-combustion engine and a piezoelectric stack supported on the micro-combustion engine so as to receive energy from the micro-combustion engine to thereby produce an electrical output.

### TECHNICAL FIELD OF THE INVENTION

The present invention relates to the generation of electricity using a piston engine.

### BACKGROUND OF THE INVENTION

Many devices, such as portable electronic devices, require a portable power supply. Two of the most popular portable power supplies are solar cells and batteries. However, solar cells cannot provide electrical power when a source of light is not available, and the amount of power delivered by solar cells is inadequate for many applications. Batteries, particularly rechargeable batteries, are heavy. Also, there are environmental concerns with the disposal of such batteries when they are spent. Therefore, the usefulness of these popular portable power supplies is limited.

Various other potentially portable power supplies, such as electromagnetic devices driven by internal combustion engines, electromagnetic devices driven by external combustion engines (Sterling engines), magneto-hydrodynamic devices (MHD), and fuel cells, have been proposed. However, it is impractical to have small micro-engines drive relatively bulky electromagnetic generators or to drive electromagnetic devices with internal or external combustion engines without relying on rotary motion, and rotary motion engines are not especially efficient. Magneto-hydrodynamic devices are not useful unless base generation systems (such as an electromechanical generation systems) are also used, and known base generation systems capable of driving magneto-hydrodynamic devices are too large for practical portable applications. Fuels cells currently operate reliably only with hydrogen. However, a practical distribution infrastructure for hydrogen does not as yet exist. Also, any power supply limited to a particular fuel is not flexible enough for the average user.

The present invention is directed to a piezoelectric device driven by a micro-engine that overcomes one or more of these or other problems.

### SUMMARY OF THE INVENTION

According to one aspect of the present invention, an electric generator comprises a micro-combustion engine and a piezoelectric stack supported on the micro-combustion engine so as to receive energy from the micro-combustion engine and to thereby generate an electrical output.

According to another aspect of the present invention, an electric generator comprises a block, a free piston, a head, a fuel inlet, an exhaust outlet, and a piezoelectric stack. The block has a return chamber, a combustion chamber, and a generator chamber. The free piston is between the return chamber and the combustion chamber and is arranged for linear movement. The head defines one end of the combustion chamber. The fuel inlet supplies fuel through the block to the combustion chamber. The exhaust outlet exhausts combustion gases from the combustion chamber. The piezoelectric stack is supported in the generator chamber so as to receive energy transmitted from the micro-combustion engine through the head.

According to still another aspect of the present invention, an electric generator comprises a block, a free piston, a head, a fuel inlet, an exhaust outlet, and a piezoelectric stack. The block has a return chamber, a combustion chamber, a generator chamber, and a head wall between the combustion chamber and the generator chamber. The return chamber, the combustion chamber, and the generator chamber are linearly arranged within the block. The free piston is supported so as to linearly move away from the combustion chamber in response to combustion in the combustion chamber and to linearly move away from the return chamber in response to the return chamber following combustion in the combustion chamber. The head extends through the head wall into the generator chamber. The fuel inlet supplies fuel through the block to the combustion chamber. The exhaust outlet exhausts combustion gases from the combustion chamber. The piezoelectric stack is supported in the generator chamber so as to receive energy transmitted from the micro-combustion engine through the head.

### BRIEF DESCRIPTION OF THE DRAWINGS

These and other features and advantages will become more apparent from a detailed consideration of the invention when taken in conjunction with the drawings in which:

FIG. 1 shows a first embodiment of a free piston piezoelectric generator;

FIG. 2 shows a second embodiment of a free piston piezoelectric generator;

FIG. 3 shows a third embodiment of a free piston piezoelectric generator; and,

FIG. 4 is a graph illustrating exemplary temperature and pressure pulses for a heptane-air mixture igniting and operating at a rate equivalent to 10,000 Hz; and,

FIG. 5 is a graph illustrating that a piezoelectric generator vibrates at its resonance frequency with an exponentially decreasing amplitude upon being “hit.”

### DETAILED DESCRIPTION

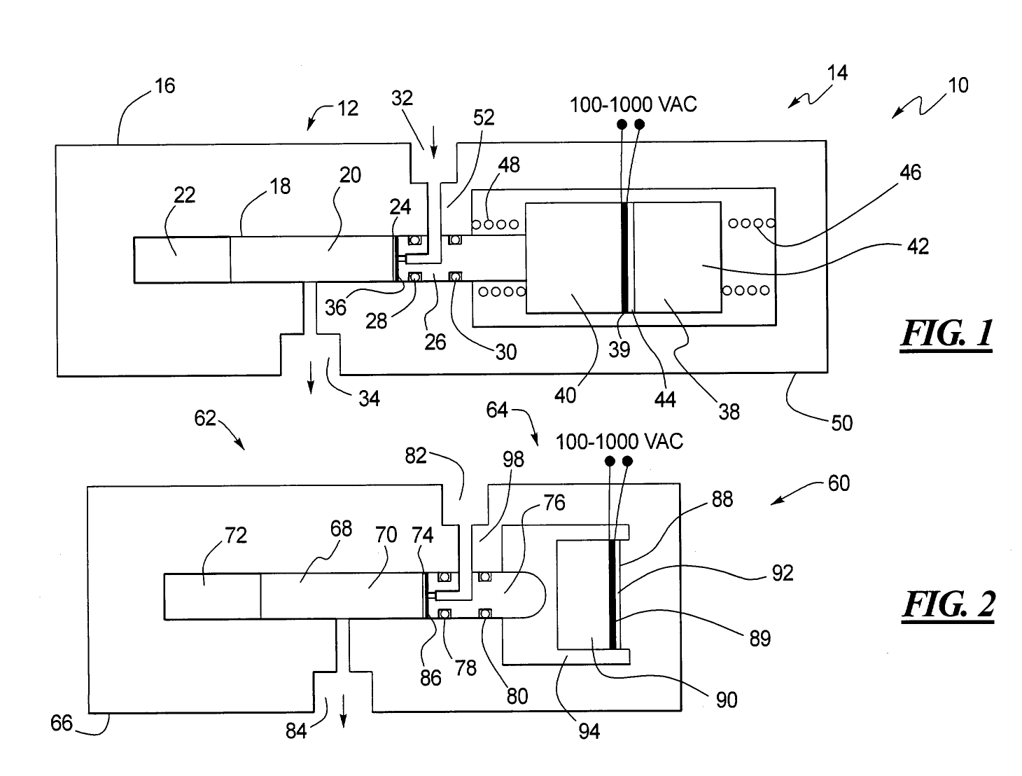

A free piston piezoelectric generator 10 according to a first embodiment of the present invention is shown in FIG. 1 and includes a free piston micro-engine 12 and a piezoelectric generator 14. Embodiments of free piston micro-engines are disclosed in U.S. Pat. Nos. 6,276,313 and 6,397,793. Basically, the free piston micro-engine 12 includes an engine block 16 defining a chamber 18 containing a free piston 20. The free piston 20 is referred to as a free piston because it is coupled to no other element such as a drive shaft. The-chamber 18 includes a return section 22 and a combustion section 24. The return section 22 of the chamber 18 functions as an air return spring to return the free piston 20 to the top of its stroke following the combustion of fuel and the exhaust of combustion gases.

A head 26 is provided in the engine block 16 between the free piston micro-engine 12 and the piezoelectric generator 14. O-rings 28 and 30 are provided around the head 26 to seal the piezoelectric generator 14 from the fuel and combustion gases of the free piston micro-engine 12. A fuel inlet channel 32 is provided through the engine block 16 and the head 26 to supply fuel to the combustion section 24 of the chamber 18. An exhaust outlet channel 34 is provided through the engine block 16 to exhaust combustion gases from the combustion section 24 of the chamber 18. A micro check valve 36 is provided at the interface between the fuel inlet channel 32 and the combustion section 24 of the chamber 18 in order to prevent fuel and combustion gases from flowing back through the fuel inlet channel 32 from the combustion section 24 of the chamber 18.

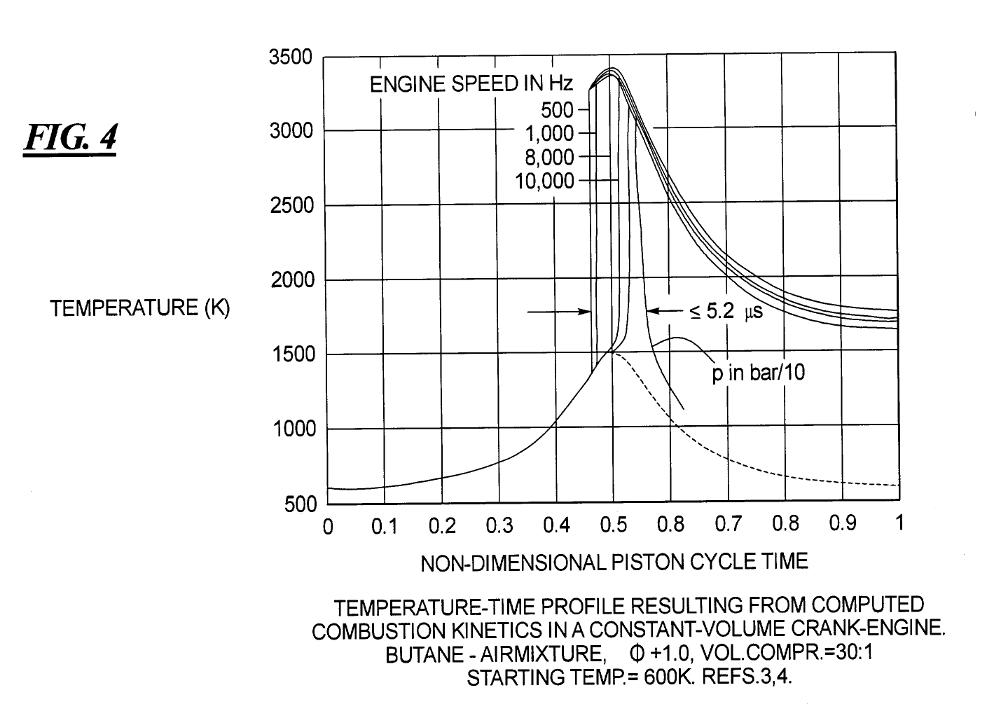

The piezoelectric generator 14 includes a piezoelectric stack 38 having one or more piezoelectric elements 39, such as discs, and inertial or resonator metal blocks 40 and 42. The piezoelectric element 39 is supported between the metal blocks 40 and 42. An electrical insulator 44 may be provided between the piezoelectric element 39 and the metal block 42 to prevent shorting of the piezoelectric output. Springs 46 and 48 (both compressive if the head 26, the metal block 40, the piezoelectric element 39, the electrical insulator 44, and the metal block 42 are cemented together) help to support, hold in place, and bias the piezoelectric stack 38 and the inertial masses within the generator block 50. Alternate methods of support are conceivable and exemplified in FIG. 3 via a step in the outside diameter of a head 116, so that only the compressive spring 46 would be needed. As a still further alternative, no spring is required if the elastic support of a resonant counter mass 136 assumes that function. The engine block 16 and the generator block 50 preferably, although not necessarily, comprise a single block.

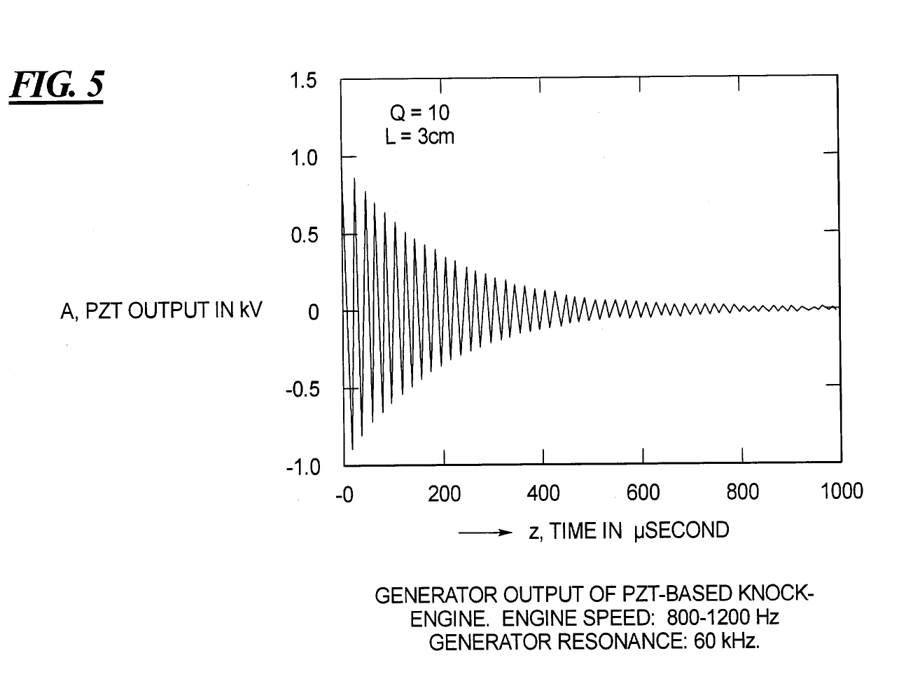

As the free piston micro-engine 12 operates, it periodically “hits” and excites the piezoelectric generator 14 so that the piezoelectric generator 14 vibrates at its resonance frequency within its spring support/suspension, with an exponentially decreasing amplitude, as illustrated in FIG. 5, until the next “hit” occurs. These “hits” are caused by very short, high pressure peaks (such as shown in FIG. 4) generated by the internal combustion of the free piston micro-engine 12. The free piston micro-engine 12 is capable of achieving a speed of 1000±200 Hz, which may be equivalent to rotary engine frequencies of ˜10, 000 Hz, as simulated in FIG. 5. A short (75 mm) block of PZT (lead zirconate titanate) resonates at 20 kHz due to its speed of sound, cₛ, which is given by the following equation:

cₛ=2fL=2(20000)(0.075)=3000 m/s.

A 1000 Hz resonator then would have to be L=cₛ/2f=1.5 m long which may be impractical for many applications, not only because of its length, but also because it can be difficult to control the engine frequency to the exact value of the PZT resonance frequency.

However, an alternative is to briefly “hit” the PZT stack and to let it ring at its own frequency and to repeat this process as often as possible. The energy produced by the PZT stack can be stored in a capacitor or battery through a full wave rectifier and supplied from the capacitor or battery to a load as necessary. One might check whether the free piston micro-engine 12 is able to hit the generator stack with a short enough pulse. Validated combustion kinetic calculations have shown that a heptane-air fuel mixture is capable of achieving top-dead center speeds equivalent to pressure pulse widths of only 5.2 μs, which is fast enough to represent a “hit” from a device oscillating at 96 kHz. Thus, this pressure pulse is short enough to excite a PZT resonator of that frequency. In this case, the PZT resonator need only be 156 mm, a much more practical length.

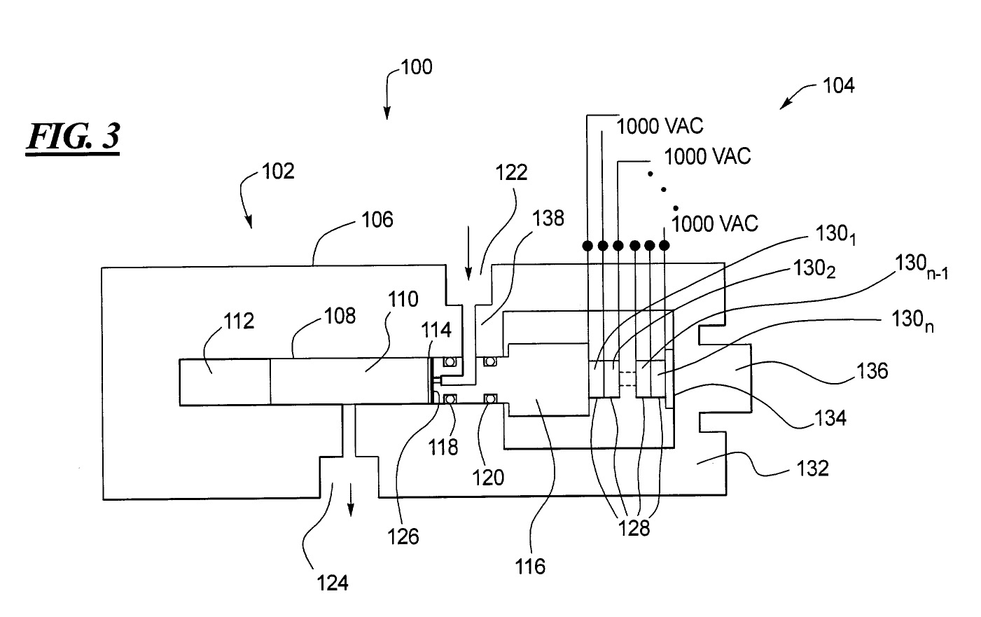

A free piston piezoelectric generator 60 according to a second embodiment of the present invention is shown in FIG. 2 and includes a free piston micro-engine 62 and a piezoelectric generator 64. Basically, the free piston micro-engine 62 includes an engine block 66 defining a chamber 68 containing a free piston 70. The chamber 68 includes a return section 72 and a combustion section 74. The return section 72 of the chamber 68 functions as an air return spring to return the free piston 70 to the top of its stroke following the combustion of fuel and the exhaust of combustion gases.

A head 76 is provided in the engine block 66 between the free piston micro-engine 62 and the piezoelectric generator 64. O-rings 78 and 80 around the head 76 seal the piezoelectric generator 64 from the fuel and combustions gases of the free piston micro-engine 62. A fuel inlet channel 82 is provided through the engine block 66 and the head 76 to supply fuel to the combustion section 74 of the chamber 68. An exhaust outlet channel 84 is provided through the engine block 66 to exhaust combustion gases from the combustion section 74 of the chamber 68. A micro check valve 86 is provided at the interface between the fuel inlet channel 82 and the combustion section 74 of the chamber 18 in order to prevent fuel and combustion gases from flowing back through the fuel inlet channel 82 from the combustion section 74 of the chamber 68.

The piezoelectric generator 64 includes a piezoelectric stack 88 having an electrical insulator 92 followed by one or more piezoelectric elements 89 and a metal block 90. The one or more piezoelectric elements 89 are supported and biased by the metal block 90. A liquid 94 is provided between the metal block 90 and the head 76 inside the engine block 66. Suitable seals (not shown) may be provided between the electrical insulator 92 and the metal block 90 to prevent leakage of the liquid 94. Alternatively, the piezoelectric generator 64 and the engine block 66 may comprise a single block.

In operation, the sharp force/pressure pulse produced by the free piston micro-engine 12 is transmitted to the piezoelectric stack 88 in order to produce the electrical output as described above. The liquid 94 helps to distribute the piston energy uniformly around the piezoelectric stack 88 with much less risk of plastic deformation of the parts of the piezoelectric generator 64. Moreover, it may be possible to design the piezoelectric generator 64 so that it has an eigen-frequency that is better matched to the operating frequency of the free piston 70 of the free piston micro-engine 62.

A free piston piezoelectric generator 100 according to a third embodiment of the present invention is shown in FIG. 3 and includes a free piston micro-engine 102 and a piezoelectric generator 104. Basically, the free piston micro-engine 102 includes an engine block 106 defining a chamber 108 containing a free piston 110. The chamber 108 includes a return section 112 and a combustion section 114. The return section 112 of the chamber 108 functions as an air return spring to return the free piston 110 to the top of its stroke following the combustion of fuel and the exhaust of combustion gases.

A head 116 is provided in the engine block 106 between the free piston micro-engine 102 and the piezoelectric generator 104. O-rings 118 and 120 around the head 116 seal the piezoelectric generator 104 from the fuel and combustion gases of the free piston micro-engine 102. A fuel inlet channel 122 is provided through the engine block 106 and the head 116 to supply fuel to the combustion section 114 of the chamber 108. An exhaust outlet channel 124 is provided through the engine block 106 to exhaust combustion gases from the combustion section 114 of the chamber 108. A micro check valve 126 at the interface between the fuel inlet channel 122 and the combustion section 114 of the chamber 108 prevents fuel and combustion gases from flowing back through the fuel inlet channel 122 from the combustion section 114 of the chamber 108.

The piezoelectric generator 104 includes a piezoelectric stack 128 comprising one or more piezoelectric elements 130₁, 130₂, . . ., 130ₙ₋₁, and 130ₙsupported by and between the head 116 and a generator block 132. The engine block 106 and/or the generator block 132 may be metal. An electrical insulator 134 may be provided on and between the piezoelectric stack 128 and the generator block 132. The resonant counter mass 136 is formed in the generator block 132 opposite the piezoelectric stack 128. The resonant counter mass 136 forms a flexible support for the piezoelectric stack 128. The generator block 132 is suitably fastened to a head wall 138 of the engine block 106. If desired, suitable seals may be provided between the engine block 106 and the generator block 132. Alternatively, the engine block 106 and the generator block 132 may comprise a single block.

In operation, a resonator is formed between a strong spring that supports the resonant counter mass 136, its own mass, the masses of the head wall 138 (which is part of block 132/106), the mass of the head 116 and the piezoelectric stack 128. This resonator resonates at the same frequency as that of the free piston micro-engine 102.

The generator of the present invention operates with smaller displacements and generates higher voltages than those generated by electromagnetic and magneto-hydrodynamic designs. The generator of the present invention operates at a higher efficiency and at less wear and friction (no side thrusts associated with crank shafts to produce rotary motion), has no moving parts except for the engine's free piston and the small displacements associated with the elasticity of the involved materials, is simpler and has a lower cost relative to compressed air and turbine generator designs, offers a higher energy density, and/or can be recharged (via refueling) more quickly than electro-chemical batteries.

FIG. 4 shows temperature pulses for butane-air mixtures and the corresponding pressure decay for a heptane-air mixture igniting and operating at 10,000 Hz. The half-height width of the pressure pulse is only t=5.2 μs, which is fast enough to represent a “hit” from a device oscillating at 1/(2×5.2·10⁻⁶)=96 kHz, and is short enough to excite a PZT resonator of that frequency. Such a PZT resonator would only require a length of L=cₛ=2 f L=156 mm. FIG. 4 shows that the pressure pulse is very narrow.

Certain modifications of the present invention may have been discussed above. Other modifications will occur to those practicing in the art of the present invention. For example, the air-spring returns formed by the return sections 22, 72, and 112 described above may be replaced by a second combustion chamber in order to achieve a double-acting generator of correspondingly higher power density. Other modifications suggested by today's art of engine design may be included, such as valveless porting of combustible mixture inlets, akin to the valveless porting for the exhaust gases shown in FIGS. 1-3.

Moreover, the resonant masses shown and described herein can be replaced by low-loss, low-sound-speed materials, such as liquids, so as to achieve the needed resonant frequency match.

Accordingly, the description of the present invention is to be construed as illustrative only and is for the purpose of teaching those skilled in the art the best mode of carrying out the invention. The details may be varied substantially without departing from the spirit of the invention, and the exclusive use of all modifications which are within the scope of the appended claims is reserved.

We claim:

1. An electric generator comprising:
a micro-combustion engine; and,
a piezoelectric stack supported on the micro-combustion engine so as to receive energy from the micro-combustion engine and to thereby generate an electrical output.

2. The electric generator of claim 1 wherein the piezoelectric stack is supported on a head wall of the micro-combustion engine.

3. The electric generator of claim 1 wherein the piezoelectric stack is supported so as to have a resonant frequency matched to an operating frequency of the micro-combustion engine.

4. The electric generator of claim 1 wherein the piezoelectric stack comprises a piezoelectric device and two metal blocks, and wherein the piezoelectric device is sandwiched between the two metal blocks.

5. The electric generator of claim 4 wherein at least one of the two metal blocks is supported by a spring.

6. The electric generator of claim 4 wherein the two metal blocks are supported by a pair of springs.

7. The electric generator of claim 4 wherein the piezoelectric stack is supported so as to have a resonant frequency matched to an operating frequency of the micro-combustion engine.

8. The electric generator of claim 1 wherein the piezoelectric stack comprises a piezoelectric device and a liquid, and wherein the liquid is arranged to transmit the energy from the micro-combustion engine to the piezoelectric device.

9. The electric generator of claim 8 wherein the piezoelectric stack further comprises a metal block, and wherein the piezoelectric device is supported by the metal block within the liquid.

10. The electric generator of claim 8 wherein the piezoelectric stack is supported so as to have a resonant frequency matched to an operating frequency of the micro-combustion engine.

11. The electric generator of claim 1 wherein the micro-combustion engine comprises a head, wherein the piezoelectric stack comprises at least one piezoelectric device sandwiched between and in contact with the head and a resonant counter mass.

12. The electric generator of claim 11 wherein the piezoelectric stack is supported so as to have a resonant frequency matched to an operating frequency of the micro-combustion engine.

13. The electric generator of claim 1 wherein the piezoelectric stack comprises more than one piezoelectric element.

14. An electric generator comprising:
a block having a return chamber, a combustion chamber, and a generator chamber;
a free piston between the return chamber and the combustion chamber and arranged for linear movement;
a head defining one end of the combustion chamber;
a fuel inlet to supply fuel through the block to the combustion chamber;
an exhaust outlet to exhaust combustion gases from the combustion chamber; and,
a piezoelectric stack supported in the generator chamber so as to receive energy transmitted from the micro-combustion engine through the head.

15. The electric generator of claim 14 wherein the piezoelectric stack is supported on the head.

16. The electric generator of claim 14 wherein the piezoelectric stack is supported within the generator chamber so as to have a resonant frequency matched to an operating frequency of the free piston.

17. The electric generator of claim 14 wherein the piezoelectric stack and inertial support masses within the generator chamber have a resonant frequency that is much higher than the operating frequency of the free piston, whereby many oscillations of decreasing amplitude and output voltage of the piezoelectric stack occur between two consecutive piston hits.

18. The electric generator of claim 14 wherein the piezoelectric stack comprises a piezoelectric device and two metal blocks, and wherein the piezoelectric device is sandwiched between the two metal blocks.

19. The electric generator of claim 18 wherein at least one of the two metal blocks is supported by a spring.

20. The electric generator of claim 18 wherein each of the two metal blocks is biased by a corresponding spring.

21. The electric generator of claim 18 wherein the piezoelectric device and the metal blocks are biased by a suitably strong but elastic clamp.

22. The electric generator of claim 18 wherein the piezoelectric stack is supported within the generator chamber so as to have a resonant frequency matched to an operating frequency of the free piston.

23. The electric generator of claim 14 wherein the piezoelectric stack comprises a piezoelectric device and a liquid, wherein the liquid is contained within the generator chamber, and wherein the liquid is arranged to transmit the energy from the head of the micro-combustion engine to the piezoelectric device.

24. The electric generator of claim 23 wherein the piezoelectric stack further comprises a metal block, wherein the piezoelectric device is supported by the metal block within the generator chamber, and wherein the metal block is between the head and the block.

25. The electric generator of claim 24 wherein the piezoelectric device and the metal block are supported on the block having the return chamber, the combustion chamber, and the generator chamber.

26. The electric generator of claim 23 wherein the piezoelectric stack is supported so as to have a resonant frequency matched to an operating frequency of the free piston.

27. The electric generator of claim 14 wherein the block has a head, wherein the piezoelectric stack comprises a piezoelectric device on and sandwiched between the head and a resonant counter mass.

28. The electric generator of claim 27 wherein the piezoelectric stack is supported so as to have a resonant frequency matched to an operating frequency of the free piston.

29. The electric generator of claim 14 wherein the return chamber forms an air-spring return for the free piston.

30. The electric generator of claim 14 wherein the piezoelectric stack comprises more than one piezoelectric element.

31. An electric generator comprising:
a block having a return chamber, a combustion chamber, a generator chamber, and a head wall between the combustion chamber and the generator chamber, wherein the return chamber, the combustion chamber, and the generator chamber are linearly arranged within the block;
a free piston supported so as to linearly move away from the combustion chamber in response to combustion in the combustion chamber and to linearly move away from the return chamber in response to the return chamber following combustion in the combustion chamber;
a head extending through the head wall into the generator chamber;
a fuel inlet to supply fuel through the block to the combustion chamber;
an exhaust outlet to exhaust combustion gases from the combustion chamber; and,
a piezoelectric stack supported in the generator chamber so as to receive energy transmitted from the micro-combustion engine through the head.

32. The electric generator of claim 31 wherein the piezoelectric stack is supported on the head.

33. The electric generator of claim 31 wherein the piezoelectric stack is supported within the generator chamber so as to have a resonant frequency matched to an operating frequency of the free piston.

34. The electric generator of claim 31 wherein the piezoelectric stack comprises a piezoelectric device and first and second metal blocks, and wherein the piezoelectric device is sandwiched between the first and second metal blocks.

35. The electric generator of claim 34 wherein at least one of the first and second metal blocks is biased by a spring.

36. The electric generator of claim 34 wherein the first metal block is biased by a first spring, wherein the second metal block is biased by a second spring, wherein the first spring is in contact with the head wall and the first metal block, and wherein the second spring is in contact with the block and the second metal block.

37. The electric generator of claim 34 wherein the piezoelectric stack is supported within the generator chamber so as to have a resonant frequency matched to an operating frequency of the free piston.

38. The electric generator of claim 31 wherein the block comprises a head, wherein the piezoelectric stack comprises a piezoelectric device and a liquid, wherein the liquid is contained within the generator chamber, and wherein the liquid is arranged to transmit the energy from the head to the piezoelectric device.

39. The electric generator of claim 38 wherein the piezoelectric stack further comprises a metal block, wherein the piezoelectric device is supported by a metal block within the generator chamber, wherein one face of the metal block faces the head, and wherein an opposite face of the metal block is in contact with the block.

40. The electric generator of claim 38 wherein the piezoelectric stack is supported so as to have a resonant frequency that is greater than or equal to an operating frequency of the free piston.

41. The electric generator of claim 31 wherein the block comprises a head, and wherein the piezoelectric stack comprises a piezoelectric device having one face in contact with the head and a second face in contact with a resonant counter mass.

42. The electric generator of claim 41 wherein the resonant counter mass is formed by the block having the return chamber, the combustion chamber, the generator chamber, and the head wall.

43. The electric generator of claim 41 wherein the piezoelectric stack is supported so as to have a resonant frequency matched to an operating frequency of the free piston.

44. The electric generator of claim 31 wherein the return chamber forms an air-spring return for the free piston.

45. The electric generator of claim 31 wherein the piezoelectric stack comprises more than one piezoelectric element.
